(19) United States
(12) Patent Application Publication
(10) Pub. No.: US 2025/0133736 A1
(43) Pub. Date: Apr. 24, 2025

(54) NON-VOLATILE MEMORY DEVICE

(71) Applicant: IOTMEMORY TECHNOLOGY INC., Taipei City (TW)

(72) Inventors: Der-Tsyr Fan, Taoyuan City (TW); I-Hsin Huang, Taoyuan City (TW); Tzung-Wen Cheng, New Taipei City (TW); Yu-Ming Cheng, Yilan County (TW); Chen-Ming Tsai, Miaoli County (TW)

(21) Appl. No.: 18/747,381

(22) Filed: Jun. 18, 2024

Related U.S. Application Data
(60) Provisional application No. 63/545,368, filed on Oct. 24, 2023.

(51) Int. Cl. H10B 41/30; H01L 21/28; H01L 29/423; H01L 29/66; H01L 29/788

(52) U.S. Cl. CPC H10B 41/30; H10D 30/0411; H10D 30/683; H10D 30/6892; H10D 64/035

(57) ABSTRACT

A non-volatile memory device includes at least one memory cell, and the memory cell includes a substrate, a select gate, a control gate, an erase gate, and a floating gate. The select gate is disposed on the substrate. The control gate is disposed on the substrate and laterally spaced apart from the select gate. The erase gate is disposed on the substrate and laterally spaced apart from the control gate, and the erase gate includes a concave corner. The floating gate is covered with the control gate and the erase gate. The floating gate includes a convex corner which faces the concave corner of the erase gate, and the vertex of the floating gate is lower than a top surface of the select gate.

### CROSS REFERENCE TO RELATED APPLICATIONS

This application claims the benefit of U.S. Provisional Application No. 63/545,368, filed on Oct. 24, 2023. The content of the application is incorporated herein by reference.

### BACKGROUND OF THE INVENTION

### 1. Field of the Invention

The invention relates to a semiconductor device, and more particularly, to a non-volatile memory device.

### 2. Description of the Prior Art

Since a non-volatile memory can, for instance, repeatedly perform operations such as storing, reading, and erasing data, and since stored data is not lost after the non-volatile memory is shut down, the non-volatile memory has been extensively applied in personal computers and electronic equipment.

A conventional structure of non-volatile memory has a stack-gate structure, including a tunneling oxide layer, a floating gate, a coupling dielectric layer, and a control gate disposed on a substrate in order. When a programming or erase operation is performed on such a flash memory device, a suitable voltage is respectively applied to the source region, the drain region, and the control gate, such that electrons are injected into a floating gate, or electrons are pulled out from the floating gate.

In the programming and erase operation of the non-volatile memory, a greater gate-coupling ratio (GCR) between the floating gate and the control gate generally means a lower operating voltage is needed for the operation, and the operating speed and the efficiency of the flash memory are significantly increased as a result. However, during programming or erase operations, electrons have to be injected into or pulled out of the floating gate through a tunneling oxide layer disposed under the floating gate, which often causes damages to the structure of the tunneling oxide layer and thus reduces the reliability of the memory device.

In order to increase the reliability of the memory device, an erase gate is adopted and incorporated into to the memory device, which is capable of pulling the electrons from the floating gate by applying a positive voltage to the erase gate. Thus, since the electrons in the floating gate is pulled out through a tunneling oxide layer disposed on the floating gate rather than through the tunneling oxide layer disposed under the floating gate, the reliability of the memory device is further improved.

The above-mentioned memory devices, along with logic devices such as transistors with planar gate structures, are typically integrated and fabricated together on the same wafer. The memory device is usually taller than the logic device because the memory device includes a stacked gate structure including a select gate and an erase gate.

During the fabrication of middle-end-of-line (MEOL) structures, a blanket interlayer dielectric (ILD) layer is formed to cover both the logic device and the memory device. Typically, after performing a planarization process on the interlayer dielectric (ILD) layer, the ILD layer above the memory device is thinner than the ILD above the logic device because of the presence of the stacked gate structure in the memory device.

To further miniaturize the line widths of all the contact plugs formed within the ILD layer, it is necessary to reduce the thickness of the ILD layer covering both the logic device and the memory device. However, if the ILD layer above the memory device becomes too thin, it may lead to unintended electrical coupling between the memory device and the interconnects above it, which adversely affects the electrical performance of the memory device.

Therefore, there remains a need for an improved structural design of memory devices.

### SUMMARY OF THE INVENTION

The invention provides a non-volatile memory device with a reduced height which is suitable to be integrated with logic devices.

According to some embodiments of the present disclosure, a non-volatile memory device includes at least one memory cell. Each memory cell includes a substrate, a select gate, a control gate, an erase gate, and a floating gate. The select gate is disposed on the substrate. The control gate is disposed on the substrate and laterally spaced apart from the select gate. The erase gate is disposed on the substrate and laterally spaced apart from the control gate, and the erase gate includes a concave corner. The floating gate is covered with the control gate and the erase gate, and the floating gate includes a convex corner. The convex corner of the floating gate faces the concave corner of the erase gate. The vertex of the convex corner of the floating gate is lower than a top surface of the select gate.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic top view of a non-volatile memory device according to some embodiments of the present disclosure.

FIG. 2 is a schematic cross-sectional view of a non-volatile memory device taken along line A-A′ of FIG. 1 according to some embodiments of the present disclosure.

FIG. 3 is an enlarged cross-sectional view of region in FIG. 2.

FIG. 4 is a schematic cross-sectional view of a non-volatile memory device and an enlarged cross-sectional view of the same according to an alternative embodiment of the present disclosure.

FIG. 5 is a schematic cross-sectional view of a non-volatile memory device and an enlarged cross-sectional view of the same according to an alternative embodiment of the present disclosure.

FIG. 6 is a schematic cross-sectional view of a non-volatile memory device and an enlarged cross-sectional view of the same according to an alternative embodiment of the present disclosure.

FIG. 7 to FIG. 12 are cross-sectional views at various stages in the manufacturing of a non-volatile memory device according to some embodiments of the present disclosure.

FIG. 13 to FIG. 17 are cross-sectional views at various stages in the manufacturing of a non-volatile memory device according to some alternative embodiments of the present disclosure.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath”, “below”, “lower”, “under”, “on”, “over”, “above”, “upper”, “bottom”, “top” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. For example, if the device in the figures is turned over, elements described as “below” and/or “under” other elements or features would then be oriented “above” and/or “over” the other elements or features. The apparatus may be otherwise oriented (rotated 90 degrees or at other orientations) and the spatially relative descriptors used herein may likewise be interpreted accordingly.

Although the disclosure is described with respect to specific embodiments, the principles of the disclosure, as defined by the claims appended herein, may obviously be applied beyond the specifically described embodiments of the disclosure described herein. Moreover, in the description of the present disclosure, certain details have been left out in order to not obscure the inventive aspects of the disclosure. The details left out are within the knowledge of a person having ordinary skill in the art.

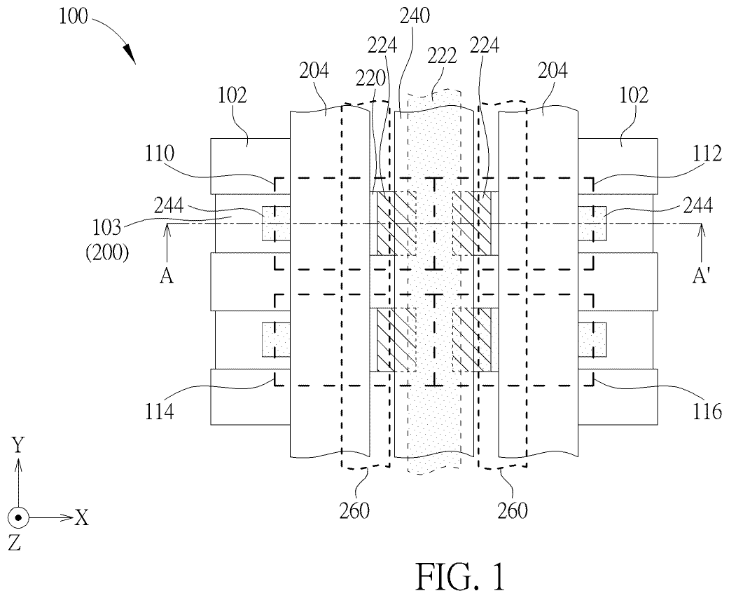

FIG. 1 is a schematic top view of a non-volatile memory device according to some embodiments of the present disclosure. Referring to FIG. 1, a non-volatile memory device 100 can be a NOR flash memory device including at least one memory cell, such as four memory cells accommodated in the first, second, third, and fourth memory cell regions 110, 112, 114, and 116, respectively. The structures in the first memory cell region 110 and the second memory cell region 112 have a mirror image of each other, and the structures in the third memory cell region 114 and the fourth memory cell region 116 have a mirror image of each other. According to one embodiment of the present disclosure, the non-volatile memory device 100 includes more than four memory cells, and these memory cells can be arranged in an array with numerous rows and columns.

Referring to FIG. 1, the non-volatile memory device 100 includes a substrate 200 and an isolation structure 102. The substrate 200 can be a semiconductor substrate, such as a silicon substrate or silicon-on-insulator (SOI) substrate, but not limited thereto. The isolation structure 102 can be made of an insulating material and is used to define active areas 103 of the memory cells.

Each of the memory cells includes a source region 222 and a drain region 244 disposed in the active area 103 defined by the isolation structure 102. The source region 222 and the drain region 244 can be doped regions of the same conductivity type, such as n-type or p-type. The conductivity type of the source region 222 and the drain region 244 is different from the conductivity type of the substrate 200, or different from the conductivity type of a doped well (not shown) used to accommodate the source region 222 and the drain region 244. The source region 222 can be disposed at one end of the active area 103, and the drain region 244 can be arranged at another end of the active area 103. According to some embodiments of the present disclosure, the source region 222 is a continuous region extending along a Y-direction and shared by the memory cells in the same column.

Each memory cell can further include a select gate 204 disposed on the substrate 200 and adjacent to the drain region 244. The select gate 204 can extend along the Y-direction and shared by the memory cells that are located in the same column. The select gate 204 can be made of conductive material such as poly silicon or metal. The select gate 204 can act as a word line configured to turn on/off the channel regions of the corresponding memory cells arranged in the same column.

An optional dielectric spacer (not shown) can be disposed on the sidewalls of the select gate 204 in order to insulate the select gate 204 from other conductive components. The dielectric spacer can be a single-layered, double-layered, or a multi-layered spacer disposed on each sidewall of the select gate 204, but not limited thereto.

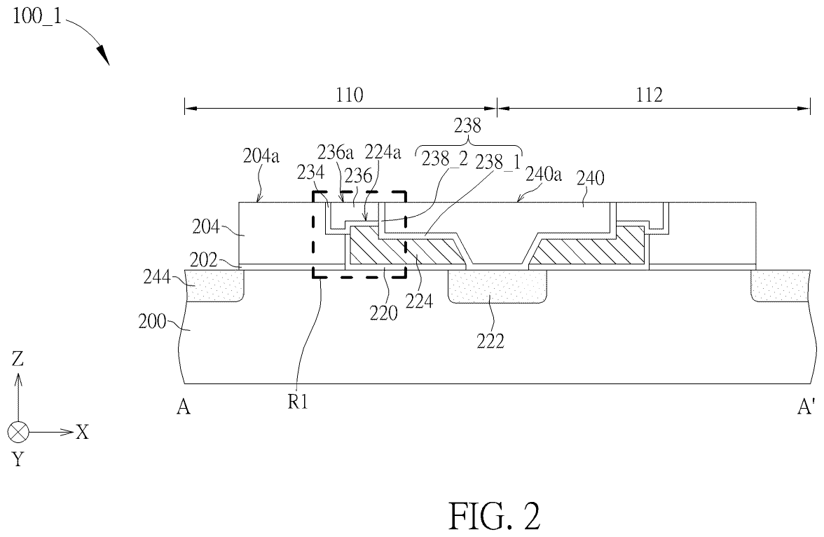

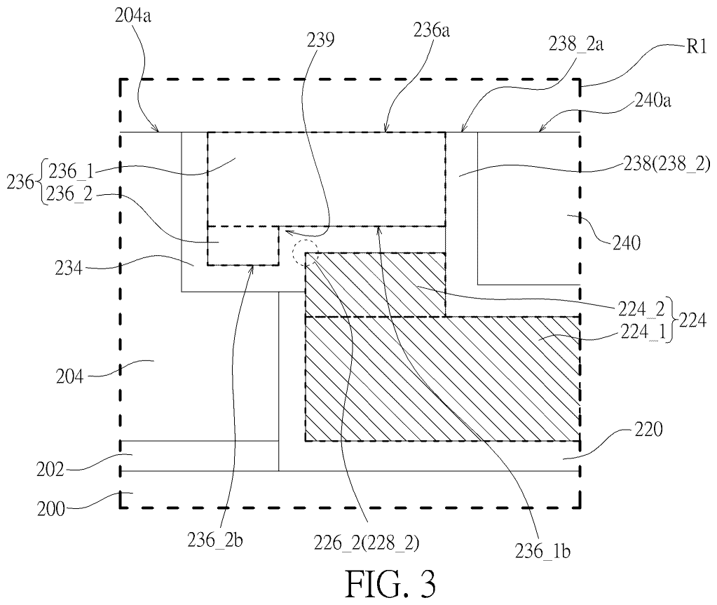

Each memory cell also includes a floating gate 224 disposed on the substrate 200 and adjacent to the source region 222. Thus, the floating gate 224 is disposed at one side of the select gate 204, and the drain region 244 is disposed at another side of the select gate 204. The floating gates 224 are made of conductive material, such as polysilicon or other semiconductor. The floating gates 224 are laterally spaced apart from each other so that the electric current could not directly transmitted between the floating gates 224. Since the floating gates 224 are spaced apart from each other, each floating gate 224 can be programed or erased independently to thereby determine the state of each memory cell, such as state “1” or state “0”. As shown in the following cross-sectional views such as FIGS. 2 and 3, each floating gate 224 is a structure with a base portion and a protruding portion. The detailed structure of the floating gate 224 is described in the description corresponding to FIGS. 2 and 3.

A floating gate dielectric layer 220 is disposed between the floating gate 224 and the select gate 204. The floating gate dielectric layer 220 also extends below the floating gate 224. The material of the floating gate dielectric layer 220 is, for instance, silicon oxide or other materials.

During a programming operation, hot electrons created under the floating gate dielectric layer 220 are allowed to be injected into and accumulate in the corresponding floating gate 224.

Each memory cell also includes a control gate 240 disposed on the substrate 200 and extending along the Y-direction. The control gate 240 is disposed in the gap between opposite select gates 204. The control gate 240 can be shared by a pair of memory cells arranged in the same row. For example, the control gate 240 can be shared by the memory cells accommodated in the first and second memory cell regions 110, 112, respectively. As the floating gate 224 including the base portion (not shown) and the protruding portion (not shown), only the base portion of the floating gate 224 is covered with the control gate 240, and the protruding portion of the floating gate 224 is laterally spaced apart from the control gate 240. The control gate 240 can cover the continuous source region 222 in a top view. The control gate 240 is made of conductive materials such as polysilicon, metal or other conductive semiconductor, but is not limited thereto.

The purpose of the control gate 240 is to make hot carriers (e.g. electrons) injected from the channel into the floating gate 224. For example, when a suitable positive voltage is applied to the control gate 240, hot carriers (e.g. electrons) transmitted in the carrier channel under the floating gate 224 can be injected to and accumulated in the corresponding floating gate 224.

The non-volatile memory device 100 further includes an erase gate (not shown) on the substrate 200, which is located in an accommodation region 260 and extends along the same direction as the source region 222 (i.e., the Y-direction). The erase gate is laterally spaced apart from the control gate 240. Depending on various design requirements, the erase gate can either cover or be spaced apart from the select gate 204. In other words, the width of the erase gate can be equal to or less than the width of the accommodation region 260. For example, when the erase gate has the same width as the accommodation region 260, the erase gate can cover portions of both the select gate 204 and the floating gate 224. In contrast, when the erase gate is narrower than the accommodation region 260, the erase gate can be laterally spaced apart from the select gate 204 while still covering a portion of the floating gate 224.

In an erasing operation of the non-volatile memory 100, the erase gate is biased, thus allowing the electrons stored in the floating gate 224 to be pulled out mainly through a tip (also called a convex corner) of the floating gate 224.

FIG. 2 is a schematic cross-sectional view of a non-volatile memory device taken along line A-A′ of FIG. 1 according to some embodiments of the present disclosure. Referring to FIG. 2, in either the first memory cell region 110 or the second memory cell region 112, the select gate 204, the erase gate 236, and the control gate 240 of a non-volatile memory device 100_1 are disposed on the substrate 200. A top surface 236a of the erase gate 236 is substantially level with a top surface 240a of the control gate 240, and even substantially level with a top surface 204a of the select gate 204.

The floating gate 224 can be an L-shaped floating gate that includes a base portion and an upwardly protruding portion (also called a protruding portion). A top surface 224a of the protruding portion is lower than the top surface 204a of the select gate 204.

An erase gate dielectric layer 234 is disposed not only between the erase gate 236 and floating gate 224, but also between the erase gate 236 and the select gate 204. The erase gate dielectric layer 234 can be made of dielectric layer which allows electrons originally stored in the floating gate 224 to pass through it by Fowler-Nordheim (FN) tunneling mechanism.

A coupling dielectric layer 238 is disposed under the control gate 240. The coupling dielectric layer 238 includes a first portion 238_1 disposed between the control gate 240 and a second portion 238_2 disposed between the control gate 240 and the erase gate 236. The coupling dielectric layer 238 can be a single dielectric layer including silicon oxide or oxynitride, or composite dielectric layer including silicon oxide/silicon nitride/silicon oxide, or any high-k dielectric layer such as many metal oxides, but is not limited thereto. In the present disclosure, a high-k dielectric layer is made of materials with the value of k greater than 4, such as HfO, HfSiO, HfAlO, or HfTaO.

According to one embodiment shown in FIG. 2, because the top surfaces 204a, 236a, 240a are substantially level with each other, the non-volatile memory device 100_1 can have a reduced height compared with another non-volatile memory device in which the erase gate is stacked on the select gate.

FIG. 3 is an enlarged cross-sectional view corresponding to region R1 of FIG. 2 according to some embodiments of the present disclosure. Referring to FIG. 3, the floating gate 224 includes a base portion 224_1 and a protruding portion 224_2 disposed on a top surface of the base portion 224_1. The base portion 224_1 can extend from below the control gate 240 to below the erase gate 236. The protruding portion 224_2 is located between the select gate 204 and the control gate 240, and is thus laterally spaced apart from the control gate 240. The protruding portion 224_2 includes a convex corner 226_2 (also called a convex upper corner) facing the erase gate 236, and a vertex 228_2 of the convex corner 226_2 of the floating gate 224 can be lower than the top surface 204a of the select gate 204.

The erase gate 236 includes a concave corner 239 at its lower half, which is faced by the convex corner 226_2 of the floating gate 224. In some embodiments, the convex corner 226_2 of the floating gate 224 may point toward the concave corner 239 of the erase gate 236.

The erase gate 236 further includes a base portion 236_1 and a protruding portion 236_2 (also called a downwardly protruding portion) disposed under the base portion 236_1. Thus, a bottom surface 236_2b of the protruding portion 236_2 is lower than a bottom surface 236_1b of the base portion 236_1.

The base portion 236_1 covers portions of both the floating gate 224 and the select gate 204, extending from above the top surface of the floating gate 224 and beyond the convex corner 226_2 of the floating gate 224. The protruding portion 236_2 is laterally spaced apart from the floating gate 224, and a portion of the select gate 204 is located between the protruding portion 236_2 and the substrate 200. In order to effectively remove the electrons stored in the floating gate 224 through the convex corner 226_2, the bottom surface 236_2b of the protruding portion 236_2 of the erase gate 236 can be modified to be lower than the vertex 228_2 of the convex corner 226_2, which causes the vertex 228_2 of the convex corner 226_2 to be partially wrapped by the erase gate 236.

For the second portion 238_2 of the coupling dielectric layer 238 that is located between the erase gate 236 and the control gate 240, a top surface 238_2a of the second portion 238_2 can be level with the top surface 236a of the erase gate 236, or even level with the top surface 240a of the control gate 240 and the top surface 204a of the select gate 204.

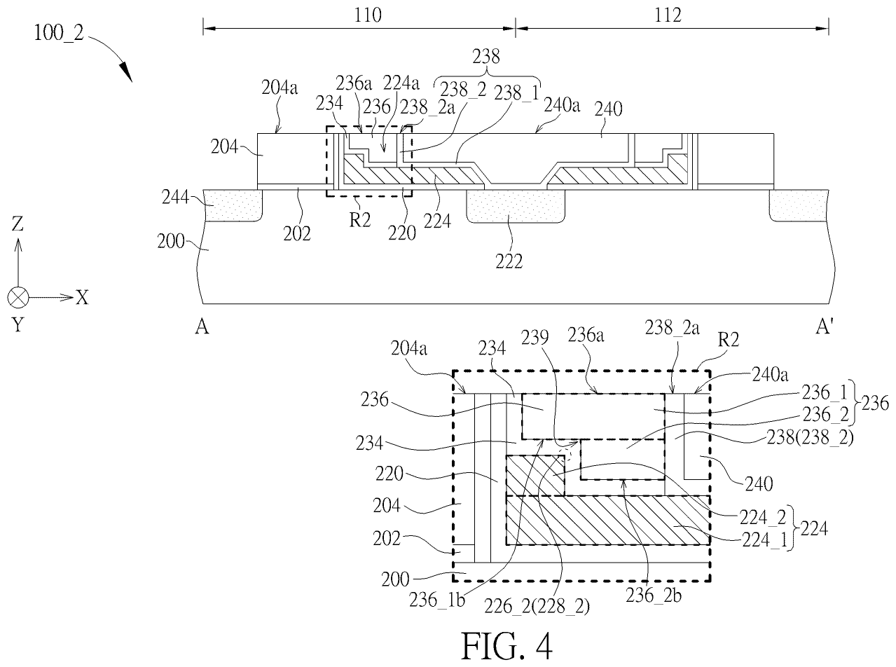

FIG. 4 is a schematic cross-sectional view of a non-volatile memory device and an enlarged cross-sectional view of the same according to an alternative embodiment of the present disclosure. The structure shown in FIG. 4 is analogous to the structures shown in FIG. 2 and FIG. 3; however, the main difference is that the erase gate 236 shown in FIG. 4 is laterally spaced apart from the select gate 204 instead of overlapping with it. In a non-volatile memory device 100_2 shown in FIG. 4, particularly in an enlarged cross-sectional view of region R2, the convex corner 226_2 of the protruding portion 224_2 of the select gate 224 still faces the concave corner 239 of the erase gate 236. However, the base portion 236_1 and the protruding portion 236_2 of the erase gate 236 are laterally spaced apart from the select gate 204. In addition, the protruding portion 236_2 of the erase gate 236 is located between the protruding portion 224_2 of the floating gate 224 and the control gate 240, covering the base portion 224_1 of the select gate 224.

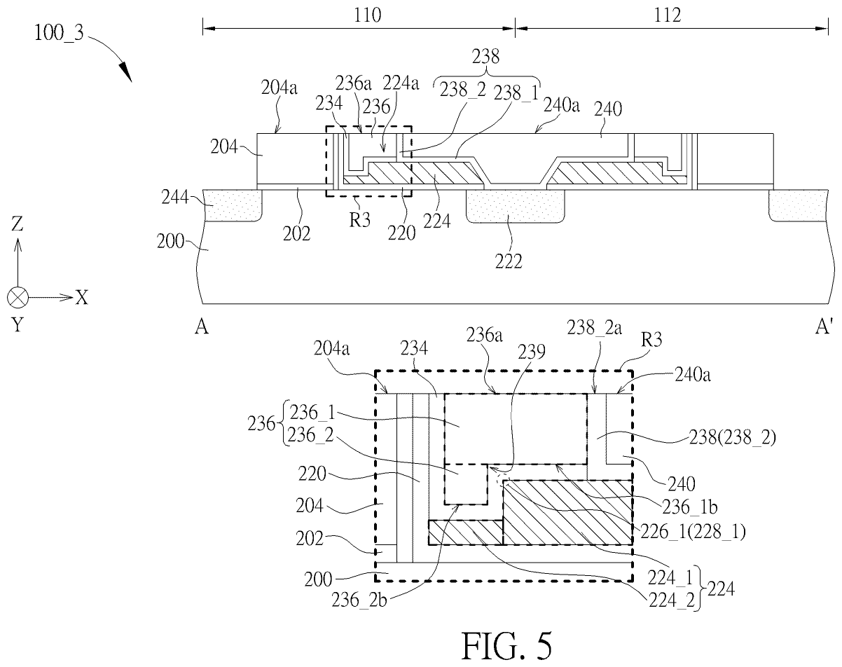

FIG. 5 is a schematic cross-sectional view of a non-volatile memory device and an enlarged cross-sectional view of the same according to an alternative embodiment of the present disclosure. The structure of a non-volatile memory device 100_3 shown in FIG. 5 is analogous to the structures shown in FIG. 2 and FIG. 3; however, the main difference is that the protruding portion 224_2 of the floating gate 224 is disposed on a sidewall, instead of on the top surface, of the base portion 224_1 of the floating gate 224. Thus, the protruding portion 224_2 can extend from the sidewall of the base portion 224_1 toward the select gate 204. The thickness of the protruding portion 224_2 is less than the thickness of the base portion 224_1, so the top surface of the protruding portion 224_2 is lower than the top surface of the base portion 224_1. Additionally, the base portion 224_1 includes a convex corner 226_1 (also called a convex upper corner) facing the erase gate 236, and a vertex 228_1 of the convex corner 226_1 of the floating gate 224 can be lower than the top surface 204a of the select gate 204.

In order to effectively remove the electrons stored in the floating gate 224 through the convex corner 226_1, the bottom surface 236_2b of the protruding portion 236_2 of the erase gate 236 can be modified to be lower than the vertex 228_1 of the convex corner 226_1. This modification causes the vertex 228_1 of the convex corner 226_1 to be partially wrapped by the erase gate 236.

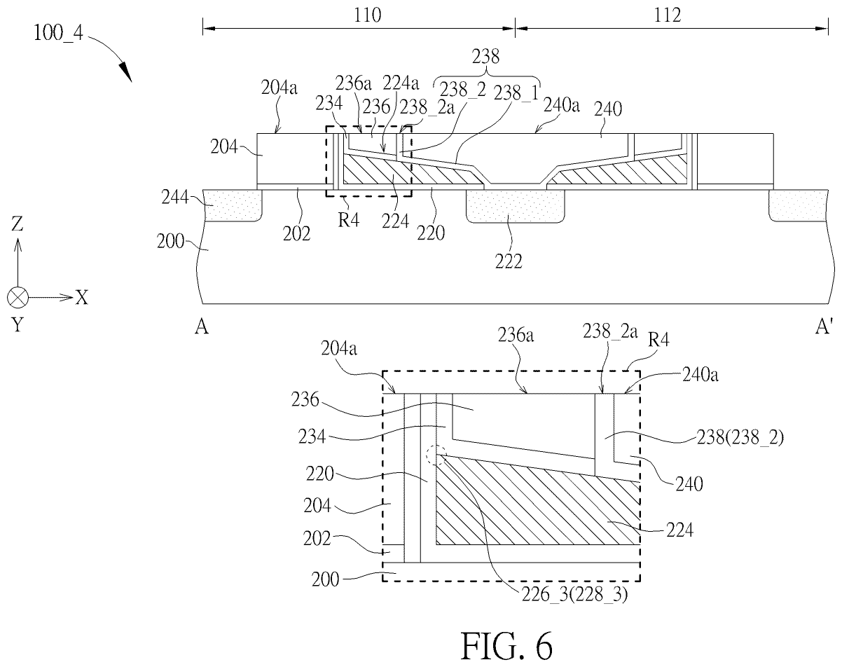

FIG. 6 is a schematic cross-sectional view of a non-volatile memory device and an enlarged cross-sectional view of the same according to an alternative embodiment of the present disclosure. The structure shown in FIG. 6 is analogous to the structures shown in FIG. 2 and FIG. 3; however, the main difference is that the erase gate 236 lacks the concave corner and does not extend beyond the sidewall of the underlying floating gate 224. The erase efficiency of the non-volatile memory device 100_4 in FIG. 6 is expected to be lower compared to previous embodiments with the convex corner 226_1, 226_2. However the memory cell of FIG. 6 is much easier to fabricate.

Additionally, the floating gate 224 includes a convex corner 226_3 (also called a convex upper corner), and a vertex 228_3 of the convex corner 226_3 can be lower than the top surface 204a of the select gate 204.

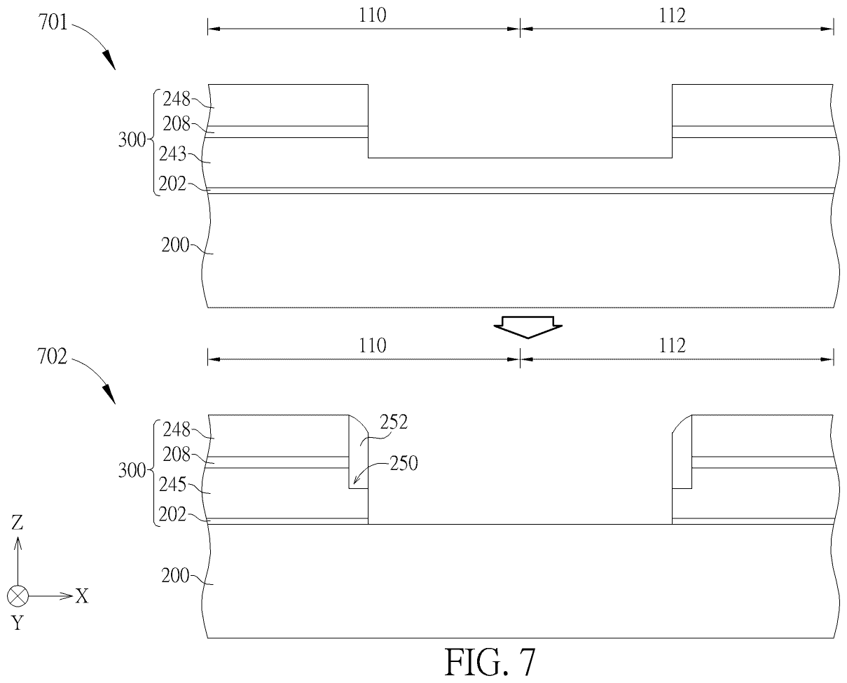

FIG. 7 to FIG. 12 are cross-sectional views at various stages in the manufacturing of non-volatile memory devices according to some embodiments of the present disclosure. The structures shown in FIG. 7 to FIG. 12 correspond to the line A-A′ of FIG. 1.

Referring to FIG. 7, in step 701, a structure formed at this manufacturing stage includes at least a substrate 200 and a stacked structure 300. The stacked structure 300 includes a select gate dielectric layer 202, a continuous select gate layer 243, an insulating layer 208, and an etch mask 248, all stacked in order.

The substrate 200 may be a semiconductor substrate of suitable conductivity type, such as p-type or n-type. The composition of the substrate 200 may include silicon, germanium, gallium nitride or other suitable semiconductor materials, but is not limited thereto.

The continuous select gate layer 243 is made of conductive material. In the subsequent manufacturing process, the continuous select gate layer 243 can be patterned or processed to form one or more select gates that are configured to turn on/off of a carrier channel (also called channel region) in the substrate 200 underlying the select gate layer when biased with a suitable voltage.

The insulating layer 208 and the etch mask 248 may be made of insulating material, such as silicon oxide, silicon nitride, or silicon oxynitride, but are not limited thereto. Since the etch selectivity of the etch mask 248 to the continuous select gate layer 243 is greater than 2, and preferably greater than 5, the etch mask 248 can be used to define a mesa region of the continuous select gate layer 243 during the etching process.

Afterward, a dielectric layer (not shown) is conformally deposited on the continuous select gate layer 243 and the etch mask 248. An anisotropic etching process is than performed on the dielectric layer to form a self-aligned etch mask 252, as shown in step 702.

In step 702, another anisotropic etching process is performed on the continuous select gate layer 243 using both the etch mask 248 and the self-aligned etch mask 252 as an etch mask. During the etching process, the continuous select gate layer 243 can be segmented to thereby form at least two select gate layers 245 (or two stacked structures 300) which are laterally spaced apart from each other.

Because the self-aligned etch mask 252 is present during the formation of the select gate layers 245, each select gate layer 245 can include a concave corner 250 that is covered by the self-aligned etch mask 252. Both the self-aligned etch mask 252 and the select gate layer 245 can extend along the Y-direction in a top-view.

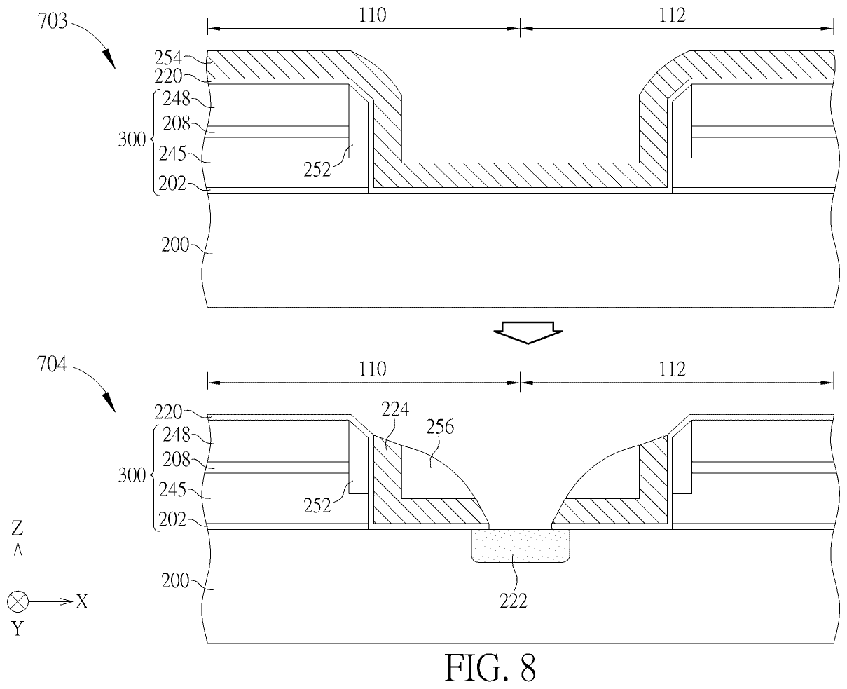

Referring to FIG. 8, in step 703, a floating gate dielectric layer 220 and a conformal floating gate layer 254 is formed on the substrate 200 and the select gate layer 245. The material of the floating gate dielectric layer 220 is, for instance, silicon oxide, or other layers that allow hot electrons pass through it. The forming method of the floating gate dielectric layer 220 is, for instance, a thermal oxidation or deposition method, but is not limited thereto. The material of the conformal floating gate layer 254 is, for instance, doped polysilicon, polycide or other suitable conductive material. When the material of the conductive layer is doped polysilicon, its forming method includes, for instance, performing an ion implantation step after an undoped polysilicon layer is formed via a chemical vapor deposition method; or performing a chemical vapor deposition method with an in-situ dopant implantation method.

Then, a photolithography and etching processes are performed to etch the conformal floating gate layer 254. As a result, the conformal floating gate layer 254 can be patterned to form a plurality of conductive strips that are separated from each other in a top view. Each of the conductive strips can extend along the X-direction, and at least in the first memory cell region 110 and the second memory cell region 112.

In step 704, after the formation of the floating gate layer 254 including several strip-shaped patterns, two self-aligned etch masks 256 are formed on a vertical surface of the floating gate layer 254. The self-aligned etch mask 256 can be made of dielectric material such as silicon oxide, silicon nitride or oxynitride, but is not limited to these materials. The self-aligned etch masks 256 are laterally spaced apart from each other, leaving the portion of the floating gate layer 254 between the self-aligned etch masks 256 exposed. The self-aligned etch mask 256 is a strip-shaped structure extending along the Y-direction in a top view.

Afterward, an etching process is performed to etch portions of the floating gate layer 254 using the self-aligned etch mask 256 as an etch mask. As a result, a floating gate 224 including a vertical portion and a horizontal portion are obtained. The floating gate 224 is a self-aligned structure, thus eliminating the need for a photolithography process to define the location of the floating gate 224. Two floating gates 224 may be formed in the first memory cell region 110 and the second memory cell region 112 respectively, and may be laterally separated from each other in the X-direction.

Then, a source region 222 is formed in the portion of the substrate 200 that is not covered by the floating gate 224. The formation of the source region 222 includes, for instance, performing an ion implantation process. The implanted dopant may be an n-type or p-type dopant as decided according to the design requirements of the device. The types and concentrations of dopants for the source region 222 may be adjusted based on actual requirements.

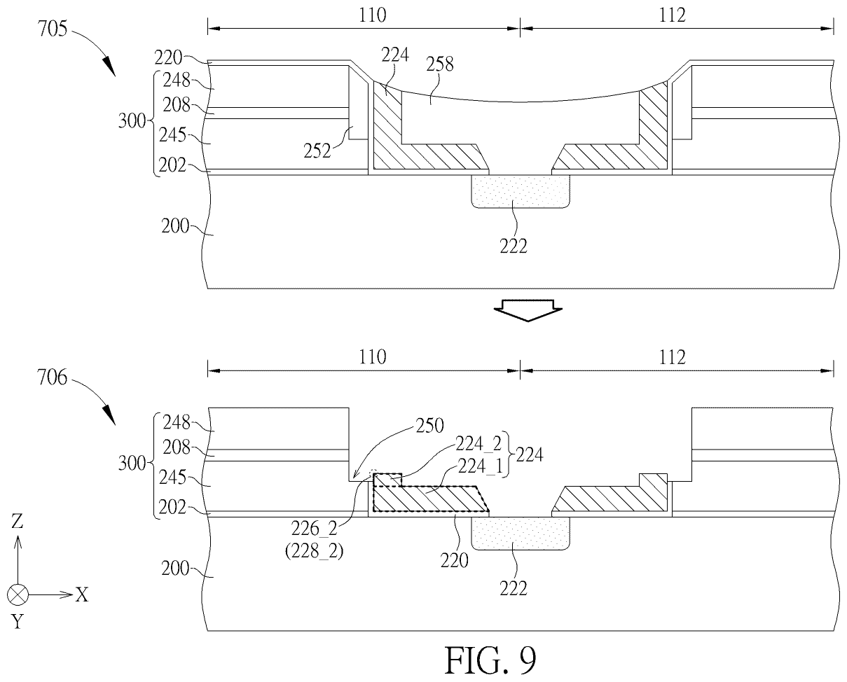

Referring to FIG. 9, in step 705, a sacrificial layer 258 can be filled into the gap at the boundary between the first memory cell region 110 and the second memory cell region 112. The sacrificial layer 258 can be formed by sequentially performing a coating process and an etching back process. During the coating process, all the components disposed on the substrate 200 can be covered by the sacrificial layer 258. Then, during the etching back process, the height of the sacrificial layer 258 can be reduced until the top surface of the sacrificial layer 258 reaches a predetermined height. Because the etch rate of the sacrificial layer 258 is greater than the etch rate of other components, such as the floating gate 224, on the substrate 200 during the etching back process, the height of the floating gate 224 can remain the same or only be slightly reduced. The sacrificial layer 258 may be made of organic materials, such as a photosensitive polymer and/or a bottom anti-reflection coating (BARC), but is not limited thereto.

In step 706, an anisotropic etching process is performed to remove all the self-aligned etch mask 252 and an upper portion of the floating gate 224 until the portion of the select gate 204 that is originally covered with the self-aligned etch mask 252 is exposed. By properly controlling the etching recipe and types or ratios of etchants, the floating gate 224 including a base portion 224_1 and a protruding portion 224_2 can be obtained when the self-aligned etch mask 252 is removed completely. The protruding portion 224_2 is disposed on the base portion 224_1, and a vertex 228_2 of a convex corner 226_2 of the protruding portion 224_2 is higher than the bottom surface of the concave corner 250 of the select gate 204.

Furthermore, during the etching of the self-aligned etch mask 252 and the floating gate 224, a portion of the sacrificial layer 258 may also be etched concurrently and the height of the sacrificial layer 258 may be slightly reduced. However, in order to protect the base portion 224_1 of the floating gate 224 from etching, a portion of the sacrificial layer 258 may still cover the base portion 224_1 when the etching process is complete. After the etching process, the remaining sacrificial layer 258 can be stripped by a wet etching process.

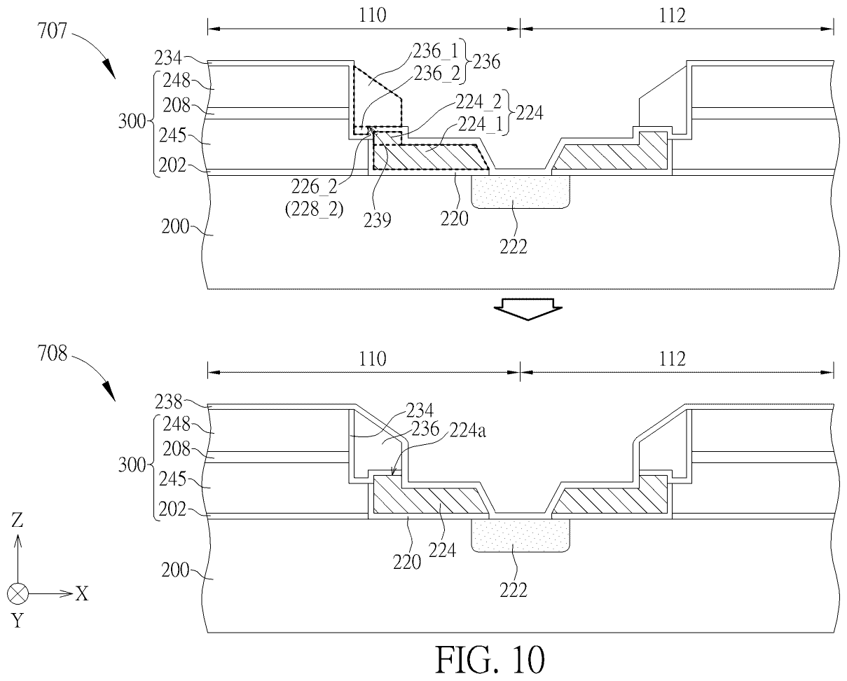

Referring to FIG. 10, in step 707, an erase gate dielectric layer 234 is formed to cover the select gate layer 245 and the floating gate 224. In some embodiments, the top surfaces of the base portion 224_1 and the protruding portion 224_2 of the floating gate 224 can be covered by the erase gate dielectric layer 234. Besides, the convex corner 226_2 can also be covered by the erase gate dielectric layer 234. The thickness of the erase gate dielectric layer 234 is less than the thickness of the floating gate 224. Then, an erase gate 236 is formed on the floating gate 224 by performing deposition and etching processes. The erase gate 236 can be a self-aligned structure with a base portion 236_1 and a protruding portion 236_2. Because of the presence of the convex corner 226_2 of the floating gate 224, the erase gate 236 may have a concave corner 239 corresponding to the location of the convex corner 226_2.

Subsequently, in step 708, a coupling dielectric layer 238 is formed to cover the base portion 224_1 of the floating gate 224 and the erase gate 236.

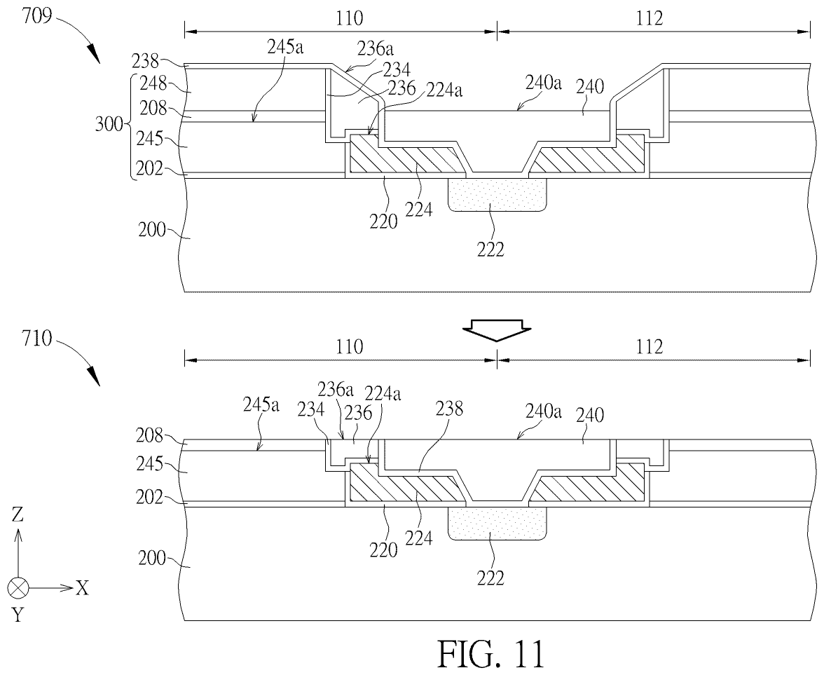

Referring to FIG. 11, in step 709, a control gate 240 is formed in the gap at the boundary of the first memory cell region 110 and the second memory cell region 112. A top surface 240a of the control gate 240 is higher than a top surface 224a of the floating gate 224 (i.e. a top surface of the protruding portion of the floating gate 224) and a top surface 245a of the select gate layer 245. The formation of the control gate 240 may include the steps of filling a conductive layer, such as polysilicon or metal, into the gap, planarizing the conductive layer, and etching back the conductive layer until its top surface reaches a predetermined height.

In step 710, a planarization process can be performed to remove the etch mask 248 located on the select gate layer 245 and to level the top surface 236a of the erase gate 236 with the top surface 240a of the control gate 240. In order to effectively remove the electrons from the floating gate 224 during an erase operation, the top surface 236a of the erase gate 236 remains higher than the top surface 224a of the floating gate 224, even after the planarization process is complete.

At this manufacturing stage, the top surface 245a of the select gate layer 245 is still covered by the insulating layer 208. However, according to various design requirements, the insulating layer 208 can also be removed during the same or an additional planarization process, and thus the top surface 245a of the select gate layer 245, the top surface 236a of the erase gate 236, and the top surface 240a of the control gate 240 can be level with each other.

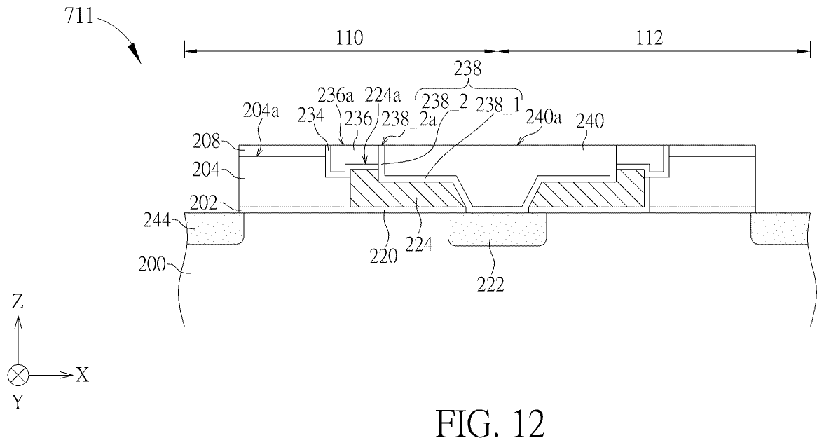

Afterward, the select gate layer 245 may be patterned to form a select gate 204 as shown in FIG. 12.

Referring to FIG. 12, in step 711, an optional dielectric spacer (not shown) may be formed on the sidewall of the select gate 204 in order to insulate the select gate 204 from other conductive components. At least one drain region 244, such as two drain regions 244, may be formed at sides of the select gates 204. The drain regions 244 are disposed in the first memory cell region 110 and the second memory cell region 112 respectively, which can be electrically coupled to each other through vias or contacts in the subsequent manufacturing processes. The forming method of the drain region 244 includes, for instance, performing an ion implantation process. The implanted dopant can be an n-type or p-type dopant as decided according to the design of the device. The dopants and the doping concentrations of the source region 222 and the drain region 244 can be the same and can also be different.

Afterwards, other electronic components can be manufactured through suitable manufacturing processes to obtain a non-volatile memory device similar to the structure shown in FIG. 1 to FIG. 3.

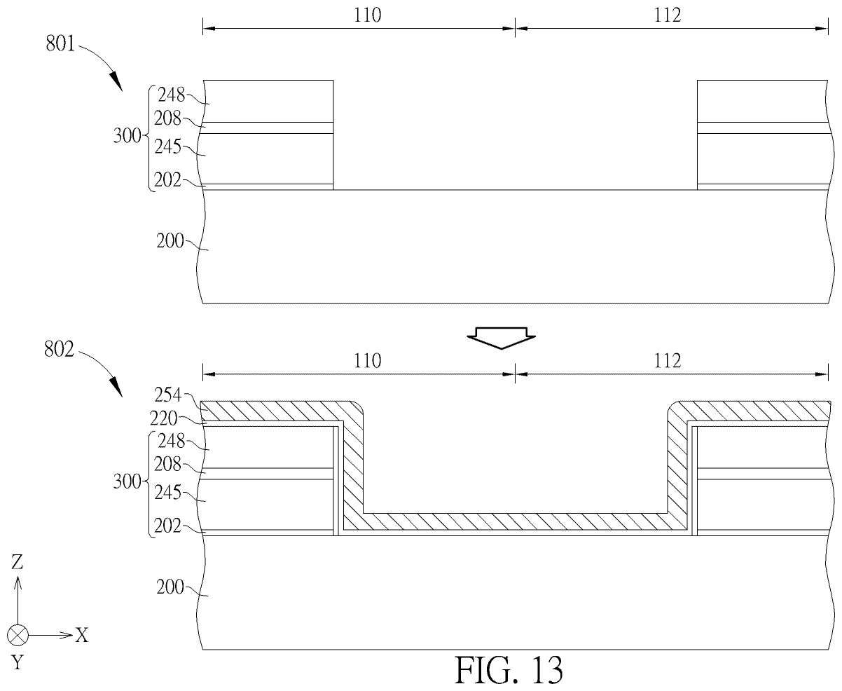

FIG. 13 to FIG. 17 are cross-sectional views at various stages in the manufacturing of non-volatile memory devices according to some embodiments of the present disclosure. Besides, since the manufacturing processes of the embodiments shown in FIG. 13 to FIG. 17 are similar to the manufacturing processes of the embodiments shown in FIG. 7 to FIG. 12, only the main differences between the embodiments are described for the sake of brevity.

Referring to FIG. 13, the manufacturing processes in steps 801 and 802 are similar to those in steps 701 to 703 as shown in FIG. 7 and FIG. 8.

In step 801, a structure formed at this manufacturing stage includes a substrate 200 and two stacked structures 300. The stacked structures 300 are laterally separated from each other, each including a select gate dielectric layer 202, a select gate layer 245, an insulating layer 208, and an etch mask 248, all stacked in order.

Afterward, in step 802, a floating gate dielectric layer 220 and a conformal floating gate layer 254 are formed on the substrate 200 and the select gate layer 245.

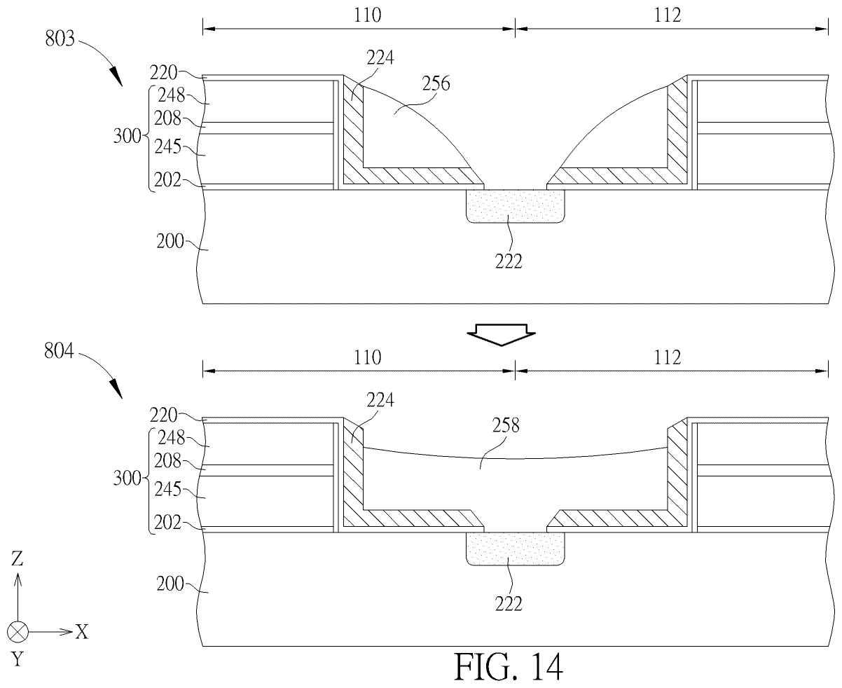

Referring to FIG. 14, the manufacturing processes in steps 803 and 804 are similar to those in steps 704 and 705 as shown in FIG. 8 and FIG. 9.

In step 803, after the formation of the floating gate layer 254 including several strip-shaped patterns, two self-aligned etch masks 256 are formed on a vertical surface of the floating gate layer 254 shown in step 802. Afterward, an etching process is performed to etch portions of the floating gate layer 254 using the self-aligned etch mask 256 as an etch mask. As a result, a floating gate 224 including a vertical portion and a horizontal portion are obtained.

In step 804, a sacrificial layer 258 can be filled into the gap at the boundary between the first memory cell region 110 and the second memory cell region 112. The sacrificial layer 258 can be formed by sequentially performing a coating process and an etching back process. During the coating process, all the components disposed on the substrate 200 can be covered by the sacrificial layer 258. Then, during the etching back process, the height of the sacrificial layer 258 can be reduced until the top surface of the sacrificial layer 258 reaches a predetermined height. Because the etch rate of the sacrificial layer 258 is greater than the etch rate of other components, such as the floating gate 224, on the substrate 200 during the etching back process, the height of the floating gate 224 can remain the same or only be slightly reduced.

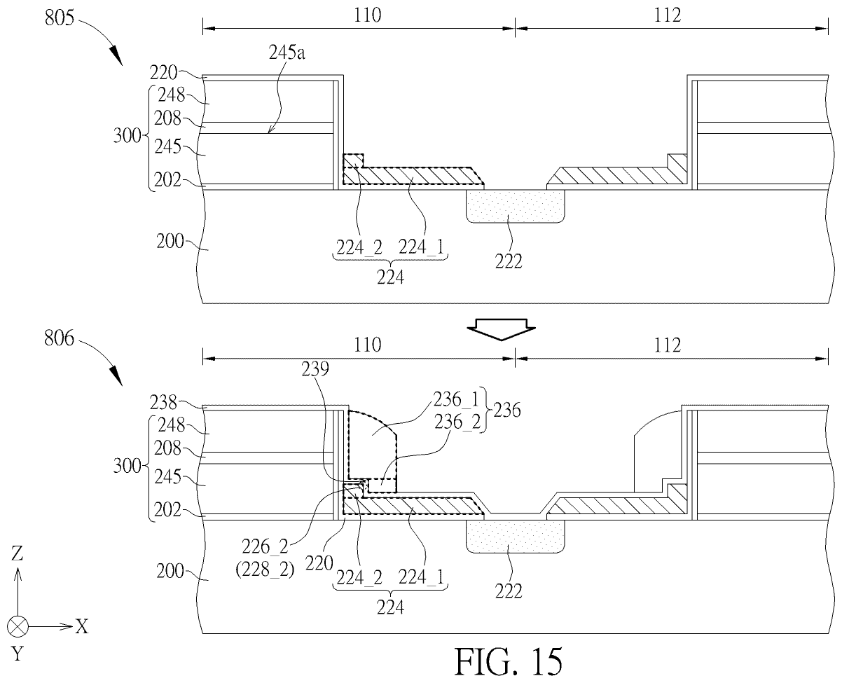

Referring to FIG. 15, the manufacturing processes in steps 805 and 806 are similar to those in steps 706 and 707 as shown in FIG. 9 and FIG. 10.

In step 805, an anisotropic etching process is performed to etch a vertical portion of the floating gate 224 until the uppermost surface of the floating gate 224 is lower than the top surface 245a of the select gate layer 245. By properly controlling the etching recipe and types or ratios of etchants, the floating gate 224 including a base portion 224_1 and a protruding portion 224_2 can be obtained. The protruding portion 224_2 is disposed on the base portion 224_1, and its vertex 228_2 is higher than the top surface of the base portion 224_1.

Furthermore, during the etching of the self-aligned etch mask 252 and the floating gate 224, a portion of the sacrificial layer 258 may also be etched concurrently and the height of the sacrificial layer 258 may be slightly reduced. After the etching process, the remaining sacrificial layer 258 can be stripped by a wet etching process.

Then, a source region 222 is formed in the portion of the substrate 200 that is not covered by the floating gate 224. requirements.

In step 806, an erase gate dielectric layer 234 is formed to cover the select gate layer 245 and the floating gate 224. The convex corner 226_2 can also be covered by the erase gate dielectric layer 234. Then, an erase gate 236 is formed on the floating gate 224 by performing deposition and etching processes. The erase gate 236 can be a self-aligned structure with a base portion 236_1 and a protruding portion 236_2, and the protruding portion 236_2 is laterally spaced apart from the select gate layer 245 and the protruding portion 224_2.

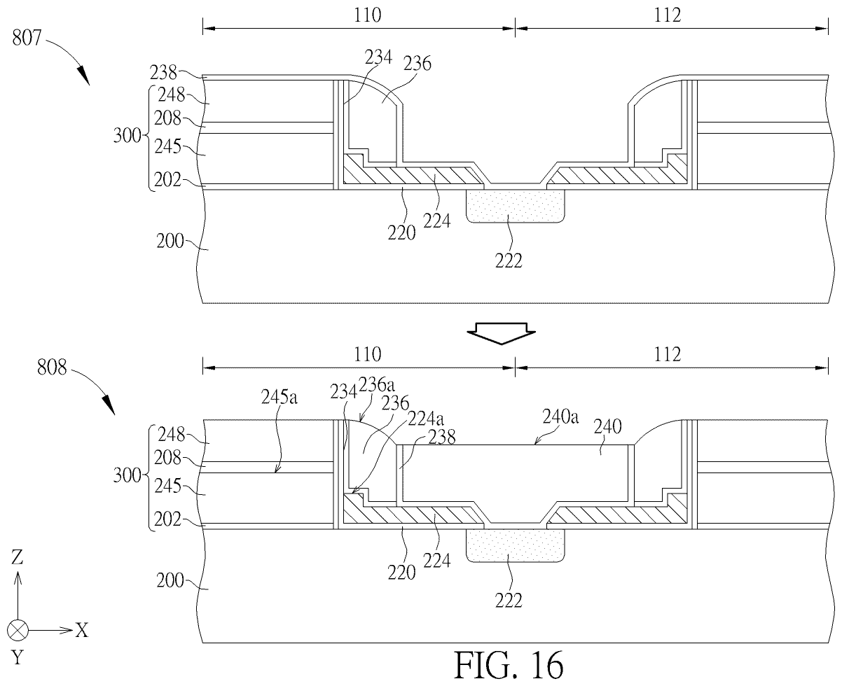

Referring to FIG. 16, the manufacturing processes in steps 807 and 808 are similar to those in steps 708 and 709 as shown in FIG. 10 and FIG. 11.

In step 807, a coupling dielectric layer 238 is formed to cover the base portion 224_1 of the floating gate 224 and the erase gate 236.

In step 808, a control gate 240 is formed in the gap at the boundary of the first memory cell region 110 and the second memory cell region 112. A top surface 240a of the control gate 240 is higher than a top surface 224a of the floating gate 224 (i.e. a top surface of the protruding portion of the floating gate 224) and a top surface 245a of the select gate layer 245.

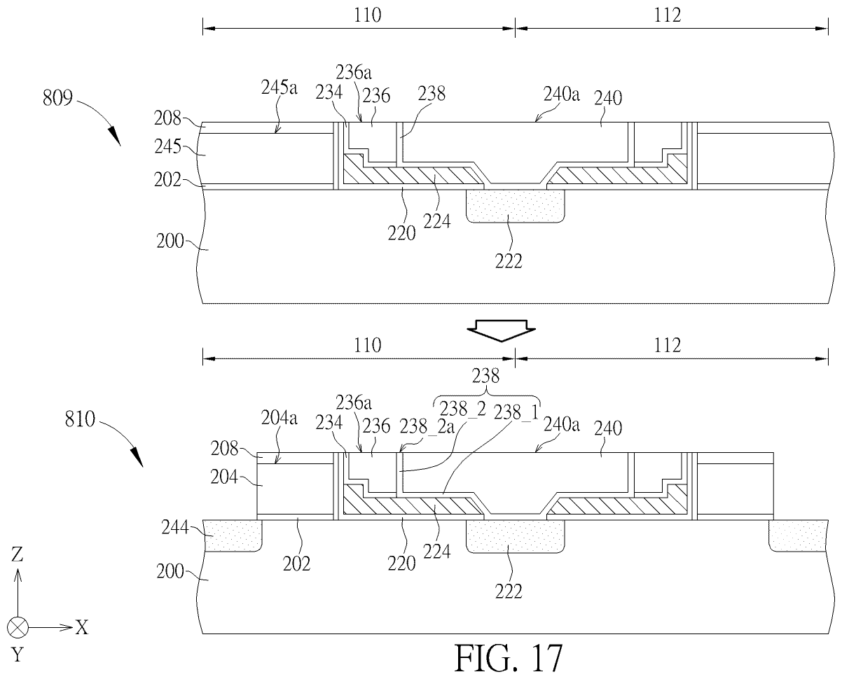

Referring to FIG. 17, the manufacturing processes in steps 809 and 810 are similar to those in steps 710 and 711 as shown in FIG. 11 and FIG. 12.

In step 809, a planarization process can be performed to remove the etch mask 248 located on the select gate layer 245 and to level the top surface 236a of the erase gate 236 with the top surface 240a of the control gate 240. In order to effectively remove the electrons from the floating gate 224 during an erase operation, the top surface 236a of the erase gate 236 remains higher than the top surface 224a of the floating gate 224, even after the planarization process is complete.

At this manufacturing stage, the top surface 245a of the select gate layer 245 is still covered by the insulating layer 208. However, according to various design requirements, the insulating layer 208 can also be removed during the same or an additional planarization process, and thus the top surface 245a of the select gate layer 245, the top surface 236a of the erase gate 236, and the top surface 240a of the control gate 240 can be level with each other.

Afterward, the select gate layer 245 may be patterned to form a select gate 204 as shown in step 810. In step 810, at least one drain region 244, such as two drain regions 244, may be formed at sides of the select gates 204, which can be electrically coupled to each other through vias or contacts in the subsequent manufacturing processes.

Afterwards, other electronic components can be manufactured through suitable manufacturing processes to obtain a non-volatile memory device similar to the structure shown in FIG. 4.

In some embodiments, for the structures shown in FIGS. 5 and 6, since these structures may be manufactured using the processes similar to those shown in FIG. 7 to FIG. 17, the corresponding manufacturing processes are omitted for the sake of brevity.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A non-volatile memory device, comprising at least one memory cell, wherein the at least one memory cell comprises:
a substrate;
a select gate disposed on the substrate;
a control gate disposed on the substrate and laterally spaced apart from the select gate;
an erase gate disposed on the substrate and laterally spaced apart from the control gate, wherein the erase gate comprises a concave corner; and
a floating gate covered with the control gate and the erase gate, wherein the floating gate comprises a convex corner,
wherein the convex corner of the floating gate faces the concave corner of the erase gate,
wherein a vertex of the convex corner of the floating gate is lower than a top surface of the select gate.

2. The non-volatile memory device of claim 1, wherein the convex corner of the floating gate points toward the concave corner of the erase gate.

3. The non-volatile memory device of claim 1, wherein a top surface of the erase gate is level with a top surface of the control gate.

4. The non-volatile memory device of claim 1, wherein a top surface of the erase gate, a top surface of the control gate, and a top surface of the select gate are level with each other.

5. The non-volatile memory device of claim 1, wherein the floating gate further comprises:
a base portion; and
a protruding portion disposed on a top surface or a sidewall of the base portion,
wherein the base portion extends from below the control gate to below the erase gate.

6. The non-volatile memory device of claim 5, wherein the protruding portion is laterally spaced apart from the control gate.

7. The non-volatile memory device of claim 5, wherein the protruding portion comprises the convex corner.

8. The non-volatile memory device of claim 5, wherein a portion of the erase gate is laterally spaced apart from the base portion.

9. The non-volatile memory device of claim 5, wherein the erase gate is disposed on the protruding portion and laterally spaced apart from the select gate.

10. The non-volatile memory device of claim 5, wherein the base portion comprises the convex corner.

11. The non-volatile memory device of claim 10, wherein the protruding portion extends from the base portion toward the select gate.

12. The non-volatile memory device of claim 10, wherein a thickness of the protruding portion is less than a thickness of the base portion.

13. The non-volatile memory device of claim 1, wherein the erase gate further comprises:
a base portion; and
a protruding portion disposed under the base portion,
wherein a bottom surface of the protruding portion is lower than a bottom surface of the base portion.

14. The non-volatile memory device of claim 13, wherein the bottom surface of the protruding portion of the erase gate is lower than the vertex of the convex corner of the floating gate.

15. The non-volatile memory device of claim 13, wherein the protruding portion of the erase gate is laterally spaced apart from the floating gate.

16. The non-volatile memory device of claim 13, wherein a portion of the select gate is disposed between the protruding portion of the erase gate and the substrate.

17. The non-volatile memory device of claim 13, wherein the protruding portion of the erase gate is laterally spaced apart from the select gate.

18. The non-volatile memory device of claim 1, further comprising a coupling dielectric layer disposed on the substrate, wherein the coupling dielectric layer comprises:
a first portion disposed between the control gate and the floating gate; and
a second portion disposed between the control gate and the erase gate, wherein a top surface of the second portion is level with a top surface of the erase gate.

19. The non-volatile memory device of claim 18, wherein the top surface of the second portion is level with a top surface of the control gate and a top surface of the select gate.

20. The non-volatile memory device of claim 1, wherein the at least one memory cell comprises a first memory cell and a second memory cell, each of the first memory cell and the second memory cell comprises the select gate, the control gate, the erase gate and the floating gate, and the non-volatile memory device further comprises a source region shared by the first memory cell and the second memory cell, wherein the source region and the erase gate extend along a same direction.
